(19) United States
(12) Patent Application Publication
(10) Pub. No.: US 2025/0365864 A1
(43) Pub. Date: Nov. 27, 2025

(54) MECHANICAL COMPONENT FOR ELECTRICAL CONTACT, AND CORRESPONDING CONTROL MODULE AND MOTOR-FAN ASSEMBLY

(71) Applicant: VALEO SYSTEMES THERMIQUES, Le Mesnil-Saint-Denis (FR)

(72) Inventors: Elmehdi Bensaih, Le Mesnil-Saint-Denis (FR); Morgan Le Goff, Le Mesnil-Saint-Denis (FR); Dineshkumar Murugan, Chennai, Tamil Nadu (IN); Alakesan Natrayan, Chennai, Tamil Nadu (IN)

(73) Assignee: VALEO SYSTEMES THERMIQUES, Le Mesnil-Saint-Denis (FR)

(21) Appl. No.: 18/875,170

(22) PCT Filed: Jun. 15, 2023
(86) PCT No.: PCT/EP2023/066056

§ 371 Date: Dec. 16, 2024

(30) Foreign Application Priority Data
Jun. 16, 2022 (FR) FR2205857

(51) Int. Cl. H05K 1/11; H05K 1/18

(52) U.S. Cl. CPC H05K 1/11; H05K 1/181; H05K 2201/1009

(57) ABSTRACT

A mechanical component for electrical contact configured to be fastened both to an electronic board and to an electrical terminal of a stator part of an electric motor of a motor-fan assembly of a heating, ventilation and/or air conditioning installation of a motor vehicle. The mechanical component includes a portion for fastening to the electronic board, configured to be inserted and soldered in a complementary hole in the electronic board, and at least two support tabs configured to rest against the electronic board and arranged on an opposite side of the mechanical component from said fastening portion with respect to a plane normal to the electronic board extending between the support tabs and the fastening portion when the mechanical component is mounted on the electronic board.

The invention relates to a mechanical component for electrical contact that makes it possible to establish electrical contact between a printed circuit on an electronic board and a stator part such as a stator winding of a motor, in particular of a motor-fan assembly for a heating, ventilation and/or air conditioning installation of a motor vehicle. The present description also relates to a control module comprising a printed circuit board and at least one such mechanical component for electrical contact fastened to the printed circuit board. The invention further relates to a motor-fan assembly, in particular for a heating, ventilation and/or air conditioning installation of a motor vehicle, comprising such a control module.

It is known practice to implement a printed circuit board in order to control a device. For example, a motor of a motor-fan assembly for a heating, ventilation and/or air conditioning installation of a motor vehicle comprises such a board in order to control the rotation of the motor of the motor-fan assembly.

Electronic and/or mechanical components are generally fastened to said printed circuit board in order to form an electronic control circuit.

Additionally, the electronic control circuit is in contact with a stator part of the motor, in particular windings of the stator, for example three in number. According to one known solution, this contact is made by means of electrical terminals or electrical contact blades, for example extending perpendicular to the printed circuit board. These electrical terminals are connected to the printed circuit board by means of a mechanical component for electrical contact known as a leadframe.

Such a mechanical component for electrical contact is generally formed from a metal plate that is cut and bent to form a flexible part having a portion intended to be fastened to an electrical terminal or an electrical contact blade, and a plurality of fastening tabs intended to be inserted into through-holes in the printed circuit board.

However, depending on the bending, the shape of the component can be difficult to produce and have a relatively large footprint, which consequently requires space on the electronic board. There is a constant aim to minimize the footprint and in particular to reduce the size of the electronic board in order to make it easier to incorporate into the motor-fan assembly, while making it possible to increase the power transmitted and reduce the electricity consumed.

In addition, the fastening tabs are generally in the form of fine rods. The fastening tabs thus aim to provide the electrical contact between the mechanical component and a printed circuit on the electronic board. These tabs can be soldered to the printed circuit board, in particular by wave soldering. In order to ensure satisfactory electrical contact, the fastening solder must extend all around each fastening tab. To achieve, this, all of the faces of each fastening tab must be covered with a layer of tin. Each mechanical component for electrical contact must thus generally be immersed in a tin bath after it has been shaped. This step is costly.

Other methods for fastening a mechanical component for electrical contact to a printed circuit board have been tested, in particular a technique known as surface mount technology or SMT. In this case, the mechanical component for electrical contact does not have fastening tabs, but has a flat surface intended to be soldered to the board, in particular the face of the board, on which the control circuit is etched. However, fastening an electrical terminal to the mechanical component for electrical contact places relatively significant stress on the mechanical component for electrical contact. The known solutions using such surface mount technology do not make it possible to produce a fastening that can withstand such stress in the long term.

Additionally, when the electronic board is being conveyed to a soldering area, the component must be held in position to prevent it falling off before soldering. According to one known solution, the component comprises additional positioning tabs intended to grip onto the electronic board. However, this adds a step to the method for assembling the component on the electronic board.

The present invention aims to propose a mechanical component for electrical contact without one or more of the drawbacks of the known mechanical components for electrical contact.

To this end, the invention relates to a mechanical component for electrical contact, made from an electrically conductive material, configured to be fastened to an electronic board so as to place a printed circuit on the electronic board in electrical contact with an electrical terminal, in particular of a stator part of an electric motor of a motor-fan assembly of a heating, ventilation and/or air conditioning installation of a motor vehicle, said component being configured to be fastened both to the electronic board and to the electrical terminal.

According to the invention, said mechanical component for electrical contact comprises a portion for fastening to the electronic board, configured to be inserted and soldered in a complementary hole in the electronic board.

Said component further comprises at least two support tabs configured to rest against the electronic board and arranged on an opposite side of said component from said fastening portion with respect to a plane normal to the electronic board extending between the support tabs and said fastening portion when said component is mounted on the electronic board.

Such a component is smaller and occupies less space on the electronic board than the solutions of the prior art, while making it possible to transmit the same, or even more, power than in the solutions of the prior art.

The portion for fastening to the electronic board, which passes through the board, makes it possible to position the component on the electronic board before soldering, and the support tabs rest against the electronic board, preventing the component from tipping, for example when the electronic board is being conveyed to a soldering area or when the conveying means stop, without requiring other positioning elements such as additional positioning tabs intended to grip onto the electronic board.

Finally, such a part is easy to manufacture and has a lower manufacturing cost than the known solutions of the prior art.

Said component can further comprise one or more of the following features described below, considered separately or in combination.

The portion for fastening to the electronic board can be configured to be inserted along an insertion axis and the component comprises at least one axial stop element configured to form a stop against the electronic board along the insertion axis.

This can be at least one shoulder, for example. According to one exemplary embodiment, the component comprises at least two shoulders on either side of the portion for fastening to the electronic board. The two shoulders can be arranged facing the two support tabs.

According to one exemplary embodiment, the portion for fastening to the electronic board is intended to be soldered in a complementary hole in a central area of the electronic board.

The portion for fastening to the electronic board, with the shoulder or shoulders, can be intended to be closer to the center of the electronic board than the support tabs.

The electronic board can be intended to be conveyed for example to a soldering area, in a direction of travel from back to front. The support tabs can be intended to be situated closer to the front periphery of the electronic board in the direction of travel. than the portion for fastening to the electronic board.

The portion for fastening to the electronic board can have an elongated transverse cross-section. It is for example rectangular.

The portion for fastening to the electronic board can form a single large fastening portion intended to be inserted into a single complementary hole in the electronic board, for example oblong in shape, which makes it possible to have a sufficient cross-section to transmit power while reducing the footprint on the electronic board compared to a solution having a plurality of fastening pins that have a smaller cross-section and must be spaced apart from each other.

Said component can comprise at least one connecting element connecting the portion for fastening to the electronic board and the support tabs.

The connecting element is for example produced in the form of a tongue.

The connecting element can extend in a plane normal to the portion for fastening to the electronic board.

According to one exemplary embodiment, the support tabs respectively have a first arm connected to the connecting element and a second arm that is bent relative to the first arm, so as to form a support foot configured to be arranged flat against the electronic board.

The support feet can rest flat against the electronic board.

The first arms of the support tabs extend for example parallel to the portion for fastening to the electronic board of the component.

The second arms of the support tabs can be bent at 90° to the first portions.

The second arms of the support tabs can extend parallel to the connecting element.

Said component can comprise one or more bends.

At least one bend can connect the connecting element to the portion for fastening to the electronic board.

At least one bend can connect the connecting element to another portion for fastening to the electrical terminal.

At least one bend can connect the connecting element to at least one support tab.

The component can thus be at least as flexible as in the solutions of the prior art, so as to reduce the transmission of vibrations from the electrical terminal of the stator part to the electronic board and reduce the risk of damaging the electronic board. The component has a shape that is simple to manufacture without the need to produce numerous bends in order to obtain this flexibility.

The bend(s) is/are for example produced in the form of at least one elbow portion. The bend(s) is/are for example produced in the form of at least one U-shaped portion.

For example, at least one U-shaped portion can connect the connecting element and the portion for fastening to the electrical terminal, extending at least partially between the support tabs, said component comprising a cavity between each support tab and the U-shaped portion.

The portion for fastening to the electrical terminal and the connecting element extend for example in two respective planes that are inclined relative to each other and form an angle greater than or equal to 100° and less than or equal to 120°.

The invention also relates to a control module, in particular for a motor-fan assembly of a heating, ventilation and/or air conditioning installation of a motor vehicle, the control module comprising an electronic board having a printed circuit and at least one mechanical component for electrical contact, as defined above, fastened to the electronic board.

The portion for fastening to the electronic board is for example soldered in a complementary hole in a central area of the electronic board, while being in electrical contact with a track of the printed circuit.

The mechanical component(s) for electrical contact is/are therefore oriented toward the inside of the electronic board. The central area is a so-called dead area, that is, it does not contain power components. This makes it possible to offer more copper surfaces on the periphery of the electronic board, and therefore more power.

According to one example, the electronic board holds at least three mechanical components for electrical contact, each one being intended to be connected to a respective phase of a brushless motor.

The invention further relates to a motor-fan assembly, in particular for a heating, ventilation and/or air conditioning installation of a motor vehicle. The motor-fan assembly comprises an electric motor having a stator part, a control module as described above, and at least one electrical terminal arranged in electrical contact both with the stator part and with the mechanical component for electrical contact.

The portion for fastening to the electrical terminal is for example soldered to the electrical terminal.

According to one embodiment, the electric motor is a brushless motor.

The stator part of the motor comprises a stator and for example at least one stator winding. The electrical terminal can be arranged in electrical contact with a stator winding.

Further advantages and features of the invention will become more clearly apparent on reading the following description, which is given by way of illustrative and non-limiting example, and the appended drawings, in which:

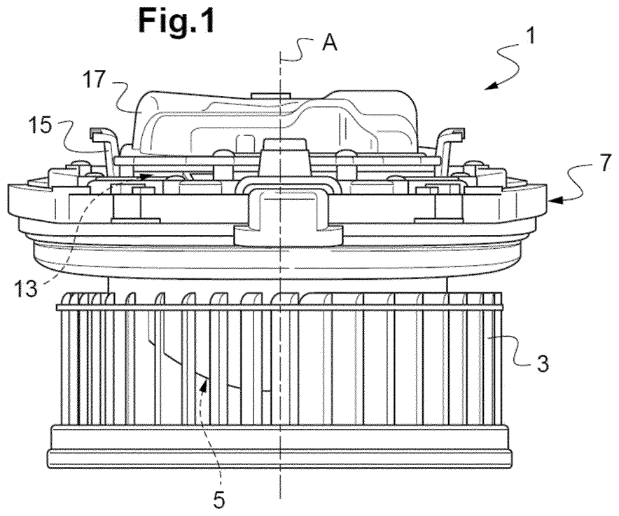

FIG. 1 shows an exemplary embodiment of a motor-fan assembly according to the invention.

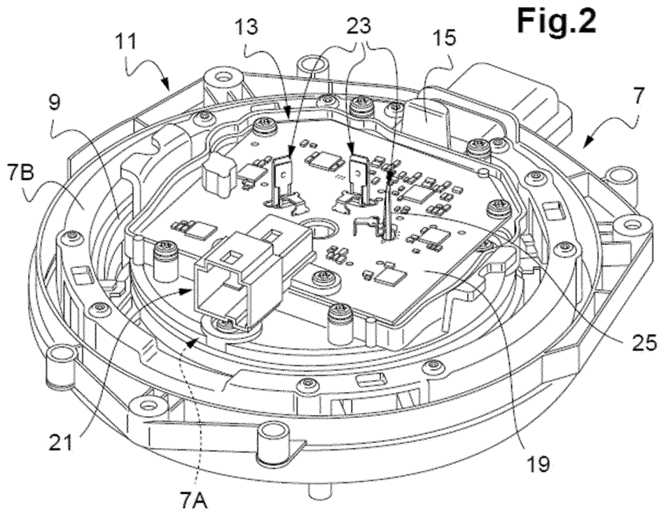

FIG. 2 shows a motor support of the motor-fan assembly in FIG. 1, to which is fastened a control module comprising an electronic board holding mechanical components for electrical contact.

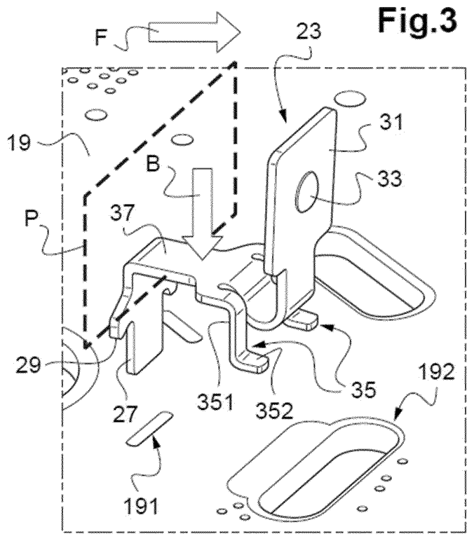

FIG. 3 is a perspective view of a mechanical component for electrical contact before assembly on the electronic board.

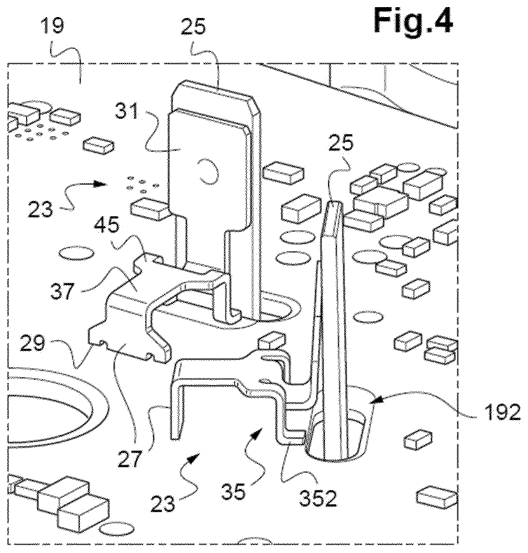

FIG. 4 is an enlarged view of FIG. 2 showing further detail of two mechanical components for electrical contact assembled on the electronic board.

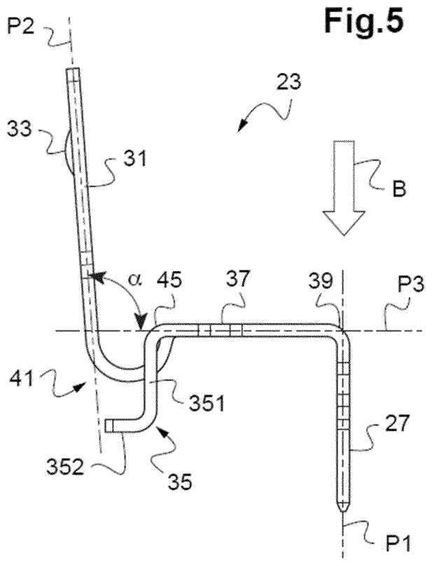

FIG. 5 is a side view of said component.

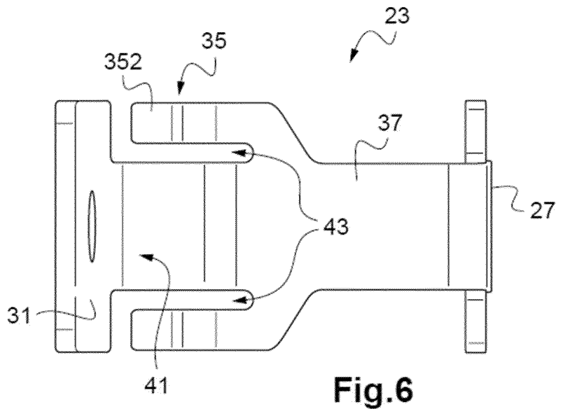

FIG. 6 is a top view of said component.

In the figures, identical elements have the same reference numbers.

The following embodiments are examples. Although the description refers to one or

more embodiments, this does not necessarily mean that each reference relates to the same embodiment, or that the features apply only to one embodiment. Individual features of different embodiments can also be combined or interchanged in order to create other embodiments.

In the description, certain elements can be given ordinal numbers, for example first element or second element. In this case, the ordinal number is simply to differentiate and denote elements that are similar but not identical. This ordinal numbering does not imply that one element takes priority over another and such numbering can easily be interchanged without departing from the scope of the present invention. Likewise, this ordinal numbering does not imply any chronological order.

FIG. 1 illustrates a motor-fan assembly 1, in particular for a heating, ventilation and/or air conditioning installation for a vehicle.

The motor-fan assembly 1 (or ventilation device) comprises in particular a fan impeller 3, an electric motor 5, and a support 7 for the motor 5, hereinafter referred to as the motor support 7.

The fan impeller 3 rotates about an axis of rotation A. The motor 5 is intended to rotate the fan impeller 3 about its axis A.

It can particularly be a brushless motor 5. The motor 5 comprises a rotor and a stator part (not visible in the figures). The rotor is for example an external rotor. The rotor can take the form of a cup fastened to a drive shaft. The fan impeller 3 can be fastened directly on the drive shaft. The rotor can comprise magnets, for example fastened to an inner face of the cup. The stator part can be internal, that is, positioned inside the rotor. The stator part comprises a stator and for example at least one stator winding, in particular three stator windings. The magnets of the rotor can be positioned radially outside the stator windings. The term radially is used relative to the axis of rotation A.

The motor support 7 is intended to make it possible to secure the motor-fan assembly 1 in a vehicle, in particular a motor vehicle.

The motor support 7, which is more clearly visible in FIG. 2, can in particular comprise two rings, an inner ring 7A and an outer ring 7B. The two rings 7A, 7B can be coaxial about an axis that coincides for example with the axis of rotation A of the fan impeller 3.

The rings 7A, 7B can be connected to each other by elastomer material. In particular, the elastomer material can form a decoupling ring 9 between the inner ring 7A and the outer ring 7B. The elastomer material is polystyrene-b-poly (ethylene-butylene)-b-polystyrene or SEBS, for example. This makes it possible to limit the transmission of the vibrations generated by the motor 5 and/or the fan impeller 3 in the vehicle and/or external stresses to the motor 5 and/or the fan impeller 3.

The inner ring 7A can be intended to be fastened to the motor 5. The outer ring 7B can be intended to be directly or indirectly fastened to a structural element, in particular of a heating, ventilation and/or air conditioning installation of a vehicle. In the example illustrated, the motor support 7 comprises a peripheral air deflector 11 to which the outer ring 7B is fastened. The air deflector 11 can be intended to be fastened to the structural element.

The motor support 7 advantageously holds a module 13 for controlling the motor 5. In particular, a support part such as a heat sink 15 can be fastened to at least one of the rings, for example the inner ring 7A, and hold the control module 7. For example, the heat sink 15 can have an indentation defining a slot for receiving the control module 13. The indentation can be surrounded by a protruding rim. Finally, with reference to FIG. 1 again, a cover 17 can be fastened to the motor support 7 so as to cap the control module 13. It can be fastened by any appropriate means, for example, but non-limitingly, by screwing. The cover 17 thus defines, with the indentation in the heat sink 15, a housing for receiving the control module 13.

The control module 13 comprises an electronic board 19 (FIG. 2) having a printed circuit.

The control module 13 can also comprise at least one connector electrically connected to the electronic board 19. This connector 21 makes it possible to supply electricity to the electronic board 19, and as a result to the motor 5, when it is connected to a wiring harness of the vehicle in particular. In particular, when the electronic board 19 is powered, the stator windings can create a magnetic field that rotates the rotor and, as a result, the fan impeller 3.

The electronic board 19 holds one or more components. They can be electronic and/or mechanical and/or mechatronic components. In particular, at least one mechanical component for electrical contact 23 is fastened to the electronic board. In the particular example illustrated, three mechanical components for electrical contact 23 can be provided, each one being intended to be connected to a respective phase of the brushless motor 5. A minimum distance must be provided between two mechanical components for electrical contact 23 in order to avoid electric arcs. This distance is adjusted depending on the power.

Such mechanical components for electrical contact 23 are known as leadframes.

Such a component 23 or leadframe is made from an electrically conductive material and makes it possible to connect, or place in electrical contact, an electrical terminal 25 arranged in electrical contact with the stator part of the motor 5, for example with a winding of the stator, to the electronic board 19, in particular to the printed circuit. The stator windings can thus be powered by means of the components 23 or leadframes and the electrical terminals 25, thus making it possible to control the motor 5.

Such a component 23 or leadframe is described in greater detail below, with reference to FIGS. 3 to 6.

The component 23 or leadframe is configured to be fastened to the electronic board 19. To this end, the component 23 or leadframe comprises a portion 27 for fastening to the electronic board 19, referred to hereinafter as the first fastening portion 27. According to the embodiment described, the component 23 or leadframe comprises a single first fastening portion 27.

The first fastening portion 27 is for example flat or substantially flat.

The first fastening portion 27 is intended to be inserted into a complementary hole 191 made in the electronic board 19. The first fastening portion 27 therefore passes through the board.

The first fastening portion 27 can have an elongated transverse cross-section. The first fastening portion 27 is for example rectangular. It is for example produced in the form of a tongue.

The complementary hole 191 is advantageously provided in a central area of the electronic board 19. More specifically, it is an area known as the dead area, that is, it does not hold any power electronics components. The power components are preferably provided on the periphery or in the vicinity of the edges of the electronic board 19. The component 23 or leadframe is positioned toward the inside of the electronic board 19. This offers more copper surfaces on the periphery, and therefore more power.

The shape of the hole 191 is complementary to the shape of the first fastening portion 27. This hole 191 can have an elongated shape. According to the embodiment shown, it is oblong or substantially oblong.

When the component 23 or leadframe is mounted on the electronic board 19, the first fastening portion 27 can thus be inserted into the hole 191 in the electronic board. There can be a single first fastening portion 27 and it can be inserted into a single complementary hole 191 in the electronic board 19. The first fastening portion 27 has a larger cross-section compared to a solution having a plurality of fastening pins that each have a smaller cross-section than the first fastening portion 27 and must be spaced apart from each other. This makes it possible to increase the mechanical strength of the component 23 or leadframe and to have a sufficient cross-section to transmit power while reducing the footprint on the electronic board 19.

The first fastening portion 27 extends for example in a first plane P1. Advantageously, this is a plane normal to the electronic board 19.

The first fastening portion 27 can be intended to be inserted along an insertion axis B. The component 23 or leadframe comprises at least one stop that rests against the electronic board 19, when the first fastening portion 27. Such a stop forms an axial stop element, that is, a stop element along the insertion axis B, which makes it possible to block the insertion movement.

There is at least one shoulder 29, for example. According to one exemplary embodiment, the component 23 or leadframe comprises at least two shoulders 29 on either side of the first fastening portion 27. The shoulder or shoulders 29 rest flat against the electronic board 19. They define a surface intended to be in contact with the electronic board 19, when the first fastening portion 27 is inserted through the electronic board 19.

The first fastening portion 27 is intended to be soldered in the complementary hole 191 made in the electronic board 19, so that it comes into electrical contact with a track of the printed circuit. This can take place by means of a wave soldering process. Electrical contact is thus provided between the electronic board 19 and the component 23 or leadframe.

In addition, the component 23 or leadframe is configured to be fastened to the electrical terminal 25. To this end, it comprises a portion 31 for fastening to the electrical terminal 25, referred to hereinafter as the second fastening portion 31. This second fastening portion 31 can be intended to be soldered to the electrical terminal 25. When it is soldered to the electronic board 19 and to the electrical terminal 25 of the stator part, the component 23 or leadframe transmits power from the electronic board 19 to the stator, for example in order to create a magnetic field and rotate the rotor.

The second fastening portion 31 can extend along a second plane P2 distinct from the first plane P1. The two planes P1, P2 are inclined relative to each other.

The second fastening portion 31 is for example rectangular. It is for example produced in the form of a tongue. The second fastening portion 31 can have a greater width than the first fastening portion 27.

Advantageously, the second fastening portion 31 has a boss 33. The boss 33 is for example convex. The boss 33 or the dome thereof is intended to be oriented towards the electrical terminal 25 of the stator part. In the example illustrated, the boss 33 is on a face of the second fastening portion 31 that is not oriented towards the first fastening portion 27. This boss 33 facilitates the electrical contact between the second fastening portion 31 and the electrical terminal 25. The second fastening portion 31 can be flat or substantially flat with the exception of the boss 33.

The component 23 or leadframe further comprises at least two support tabs 35. These support tabs 35 are intended to rest against the electronic board 19 when the first fastening portion 27 is inserted into the complementary hole 191.

The support tabs 35 can be arranged facing the first fastening portion 27 and the shoulder or shoulders 29.

The support tabs 35, and the first fastening portion 27 and the shoulder or shoulders 29, can be arranged on two opposite sides of the component 23 or leadframe. These are opposite sides with respect to a plane P normal to the electronic board 19 extending between the support feet 35 and the first fastening portion 27 when the component 23 or leadframe is mounted on the electronic board 19. It is for example a plane P parallel to the first plane P1.

In particular, two shoulders 29 can be arranged facing the two support tabs 35.

In order to position the component 23 or leadframe before soldering, the first fastening portion 27 that is intended to be soldered can be inserted into the complementary hole 191 in the electronic board and the support tabs 35 rest against the electronic board 19. There is no need to provide other positioning elements such as additional positioning tabs intended to be inserted into or grip onto the electronic board.

The first fastening portion 27, with the shoulder or shoulders 29, can be intended to be closer to the center of the electronic board 19 than the support tabs 35.

The electronic board 19 can be intended to be conveyed for example to a soldering area, in a direction of travel from back to front, represented by the arrow F. The support tabs 35 can be intended to be situated closer to the front periphery of the electronic board 19 in the direction of travel. than the first fastening portion 27.

These support tabs 35 make it possible to limit, or prevent, the tipping of the component 23 or leadframe when the electronic board 19 is being conveyed. In particular, the support tabs 35 make it possible to prevent the component 23 or leadframe from tipping forwards, or even to prevent it from falling off, when the means conveying the electronic board 19 stop.

Advantageously, the support tabs 35 are intended to be flat against the electronic board 19. By way of example, the support tabs 35 each have a first arm 351 and a second arm 352.

The first arm 351 extends for example parallel to the first fastening portion 27 of the component 23 or leadframe.

The second arm 352 is bent relative to the first arm 351, for example by 90°. This second arm 352 forms a support foot intended to be arranged flat, or resting flat, against the electronic board 19.

The support tabs 35, and more particularly the second arms 352 thereof forming support feet, can be arranged behind, in the direction of travel, another hole 192 made in the electronic board 19 through which an electrical terminal 25 is intended to pass. This other hole 192 can be elongated, for example oblong or substantially oblong.

Additionally, the component 23 or leadframe can comprise at least one connecting element 37 connecting the first fastening portion 27 and the support tabs 35. More specifically, the first arms 351 of the support tabs 35 are connected to the connecting element 37. This connecting element 37 can also connect the first fastening portion 27 and the second fastening portion 31.

The connecting element 37 can extend in a third plane P3 distinct from the first plane P1 and/or the second plane P2. This third plane P3 is inclined relative to the first plane P1 and/or the second plane P2. By way of example, the connecting element 37 can extend in a plane P3 normal to the first fastening portion 27. The third plane P3 can be inclined relative to the second plane P2 by an angle α that is for example greater than 90°. The angle α between these two planes P2, P3 is preferably between 100° and 120°.

The second arms 352 of the support tabs 35 can extend parallel to the connecting element 37.

The connecting element 37 can be flat or substantially flat. It is for example produced in the form of a tongue. The connecting element 37 can be at least partially rectangular. In the example illustrated, the connecting element 37 is rectangular, having a first side connected to the first fastening portion 27. The shape of the connecting element 37 can optionally be enlarged on a second side opposite the first side with respect to the plane P normal to the electronic board 19. The enlarged side of the connecting element 37 defines an outline that is close for example to a trapezoid.

The connecting element 37 can at least partially have a similar width to the first fastening portion 27. According to one particular exemplary embodiment, the for example rectangular part of the connecting element 37 can have the same or a substantially greater width than the first fastening portion 27. The width of the rectangular part of the connecting element 37 can be less than the width of the second fastening portion 31.

Finally, the component 23 or leadframe can comprise one or more bends giving it flexibility. This flexibility, or elasticity, of the component 23 or leadframe makes it possible to limit the stresses exerted on the first fastening portion 27. Vibrations can thus be filtered. In other words, this makes it possible to reduce the transmission of vibrations from the electrical terminal 25 to the electronic board 19, thus preventing the electronic board 19 from being damaged.

The bend(s) is/are for example produced in the form of at least one elbow portion and/or at least one U-shaped portion.

By way of example, at least one bend connecting the connecting element 37 to the first fastening portion 27 can be provided. This can be an elbow portion 39. According to the example illustrated, the elbow portion 39 is curved at a right angle.

As a variant or in addition, at least one bend connecting the connecting element 37 to the second fastening portion 31 can be provided. This can for example be a U-shaped portion 41. This U-shaped portion 41 can extend at least partially between the support tabs 35. To this end, the component 23 or leadframe comprises a cavity 43 between each support tab 35 and the U-shaped portion 41.

The U-shaped portion 41 can have a similar width to the first fastening portion 27 and/or the rectangular part of the connecting element 37.

According to another variant or in addition, at least one bend connecting the connecting element 37 to a support tab 35 can be provided. This can be an elbow portion 45. According to the example illustrated, the elbow portion 45 is curved at a right angle.

Additionally, the different portions of the component 23 or leadframe can have a constant or substantially constant thickness.

Such a component 23 or leadframe can thus be produced simply so as to optimize the space necessary on the electronic board 19 while allowing power transmission, when it is soldered to the electronic board 19 and to the electrical terminal of the stator part.

The first fastening portion 27 makes it possible to position the component 23 or leadframe on the electronic board 19 before soldering, and the support tabs 35 on the opposite side ensure the stability of the component 23 or leadframe, preventing it from tipping or falling off before soldering.

There can be a single fastening portion 27 that is larger than in the solutions of the prior art having a plurality of fastening pins that have a smaller cross-section and must be spaced apart from each other, which makes it possible to have a sufficient cross-section to transmit power while reducing the footprint on the electronic board 19.

In addition, the shoulder or shoulders 29 make it possible to increase the stability of the component 23 or leadframe on the electronic board 19.

Finally, due to the elbow or U-shaped portions, the component 23 or leadframe is at least as flexible as the solutions of the prior art, which makes it possible to filter vibrations and prevent damage to the electronic board 19.

1. A mechanical component for electrical contact, made from an electrically conductive material, configured to be fastened to an electronic board so as to place a printed circuit on the electronic board in electrical contact with an electrical terminal of a stator part of an electric motor of a motor-fan assembly of a heating, ventilation and/or air conditioning installation of a motor vehicle, said component being configured to be fastened both to the electronic board and to the electrical terminal, the mechanical component comprises:
a portion for fastening to the electronic board, configured to be inserted and soldered in a complementary hole in the electronic board; and
at least two support tabs configured to rest against the electronic board and arranged on an opposite side of said component from said fastening portion with respect to a plane normal to the electronic board extending between the support tabs and said fastening portion when said component is mounted on the electronic board.

2. The mechanical component as claimed in claim 1,
wherein the portion for fastening to the electronic board is configured to be inserted along an insertion axis, and
the mechanical component comprises at least one axial stop element configured to form a stop against the electronic board along the insertion axis.

3. The mechanical component as claimed in claim 1, wherein the portion for fastening to the electronic board has an elongated transverse cross-section.

4. The mechanical component as claimed in claim 1, further comprising at least one connecting element connecting the portion for fastening to the electronic board and the support tabs.

5. The mechanical component as claimed in claim 4, wherein the support tabs respectively have:
a first arm connected to the connecting element; and
a second arm bent relative to the first arm, so as to form a support foot configured to be arranged flat against the electronic board.

6. The mechanical component as claimed in claim 4, comprising:
at least one bend connecting the connecting element to the portion for fastening to the electronic board;
at least one bend connecting the connecting element to another portion for fastening to the electrical terminal; and/or
at least one bend connecting the connecting element to at least one support tab.

7. The mechanical component as claimed in claim 6, comprising;
at least one U-shaped portion connecting the connecting element,
wherein the portion for fastening to the electrical terminal, extending at least partially between the support tabs; and
a cavity between each support tab and the U-shaped portion.

8. A control module for a motor-fan assembly of a heating, ventilation and/or air conditioning installation of a motor vehicle, the control module comprising:
an electronic board having a printed circuit; and
at least one mechanical component for electrical contact as claimed in claim 1, fastened to the electronic board, the portion for fastening to the electronic board being soldered in a complementary hole in a central area of the electronic board, while being in electrical contact with a track of the printed circuit.

9. A motor-fan assembly for a heating, ventilation and/or air conditioning installation of a motor vehicle, comprising:
an electric motor having a stator part,
a control module as claimed in claim 8, and
at least one electrical terminal arranged in electrical contact both with the stator part and with the mechanical component for electrical contact.

10. The motor-fan assembly as claimed in claim 9, wherein the electric motor is a brushless motor.
